(19) United States
(12) Patent Application Publication
(10) Pub. No.: US 2017/0198391 A1
(43) Pub. Date: Jul. 13, 2017

(54) SUBSTRATE PROCESSING APPARATUS

(71) Applicant: HITACHI KOKUSAI ELECTRIC INC., Tokyo (JP)

(72) Inventor: Hiroshi ASHIHARA, Toyama-shi (JP)

(73) Assignee: HITACHI KOKUSAI ELECTRIC INC., Tokyo (JP)

(21) Appl. No.: 15/073,951

(22) Filed: Mar. 18, 2016

(30) Foreign Application Priority Data
Jan. 8, 2016 (JP) 2016-002530

(51) Int. Cl. C23C 16/44; H01L 21/67; C23C 16/34; C23C 16/50; H01J 37/32; B25J 11/00; C23C 16/455

(52) U.S. Cl. CPC C23C 16/4412; B25J 11/0095; H01L 21/67173; H01L 21/67167; H01L 21/67196; C23C 16/45544; C23C 16/45542; C23C 16/50; H01J 37/32834; H01J 37/32899; H01J 37/32522; C23C 16/345; H01J 37/32743; H01J 37/32788; H01J 2237/3321

(57) ABSTRACT

A technique for performing high-temperature substrate processing includes a plurality of chambers where substrates are processed, wherein the chambers are disposed adjacent to one another; a gas supply unit configured to alternately supply first and second gasses to each of the chambers; a first exhaust pipe installed in each of the chambers and configured to exhaust the first and second gasses; a first heater installed at the first exhaust pipe and configured to heat the first exhaust pipe to a temperature higher than a temperature whereat a source of the first gas is vaporized under vapor pressure; an electronic box installed at each of the chambers, wherein the electronic box is disposed adjacent to a gas box accommodating a portion of the first exhaust pipe; and a thermal reduction structure surrounding the first exhaust pipe and configured to reduce heat from the first heater being conducted to the electronic box.

### CROSS-REFERENCE TO RELATED PATENT APPLICATION

This non-provisional U.S. patent application claims priority under 35 U.S.C. §119 of Japanese Patent Application No. 2016-002530, filed on Jan. 8, 2016, the entire contents of which are hereby incorporated by reference.

### BACKGROUND OF THE INVENTION

1. Field of the Invention

The present invention relates to a substrate processing apparatus.

2. Description of the Related Art

A substrate processing apparatus such as a semiconductor manufacturing apparatus configured to perform a predetermined process on a semiconductor substrate may include a plurality of chambers in order to achieve high productivity. For example, the substrate processing apparatus may include a cluster type device in which a plurality of chambers are radially disposed.

### CITATION LIST

### Patent Literature

1. Japanese Unexamined Patent Application No. 2012-54536

The substrate processing apparatus including a plurality of chambers described above can perform a high-temperature process on a substrate in each chamber. In order to perform the high-temperature process, the substrate processing apparatus includes a heater installed in the vicinity of each chamber. However, since the chambers adjacent to each other are influenced by heat, components such as a valve whose operation efficiency decreases at high temperatures may be negatively influenced.

In view of such a problem, the present invention provides a technique by which it is possible to perform a high-temperature process in a device including a plurality of chambers.

### SUMMARY OF THE INVENTION

According to an aspect of the present invention, there is provided a substrate processing technique including:

a process module including a plurality of chambers where substrates are processed, wherein the plurality of chambers are disposed adjacent to one another;

a gas supply unit configured to alternately supply a first gas and a second gas to each of the plurality of chambers;

a first exhaust pipe installed in each of the plurality of chambers and configured to exhaust the first gas and the second gas;

a first heater installed at the first exhaust pipe and configured to heat the first exhaust pipe to a temperature higher than a temperature whereat a source of the first gas is vaporized under vapor pressure;

an electronic box installed at each of the plurality of chambers, wherein the electronic box disposed adjacent to a gas box accommodating a portion of the first exhaust pipe; and

a thermal reduction structure surrounding the first exhaust pipe and configured to reduce a heat from the first heater being conducted to the electronic box.

### BRIEF DESCRIPTION OF THE DRAWINGS

FIG. 1 is a cross-sectional view exemplifying a substrate processing apparatus according to an embodiment of the present invention.

FIG. 2 is a vertical cross-sectional view illustrating the substrate processing apparatus according to the embodiment of the present invention taken along line α-α′ of FIG. 1.

FIG. 3 is a diagram exemplifying a module according to an embodiment of the present invention and a peripheral configuration thereof.

FIG. 4 is a diagram describing a chamber according to an embodiment of the present invention and a peripheral structure thereof.

FIG. 5 is a plan view illustrating a case in which a chamber of a cluster device according to an embodiment of the present invention is not provided.

FIG. 6 is a flowchart illustrating a substrate process according to an embodiment of the present invention.

FIG. 7 is a flowchart illustrating a substrate process according to an embodiment of the present invention.

FIG. 8 is a diagram describing a situation of gases according to an embodiment of the present invention.

FIG. 9 is a diagram describing a thermal reduction structure and an exhaust pipe according to an embodiment of the present invention.

### DETAILED DESCRIPTION OF THE PREFERRED EMBODIMENTS

### First Embodiment

Hereinafter, a substrate processing apparatus according to a first embodiment of the present invention will be described.

(1) Configuration of Substrate Processing Apparatus

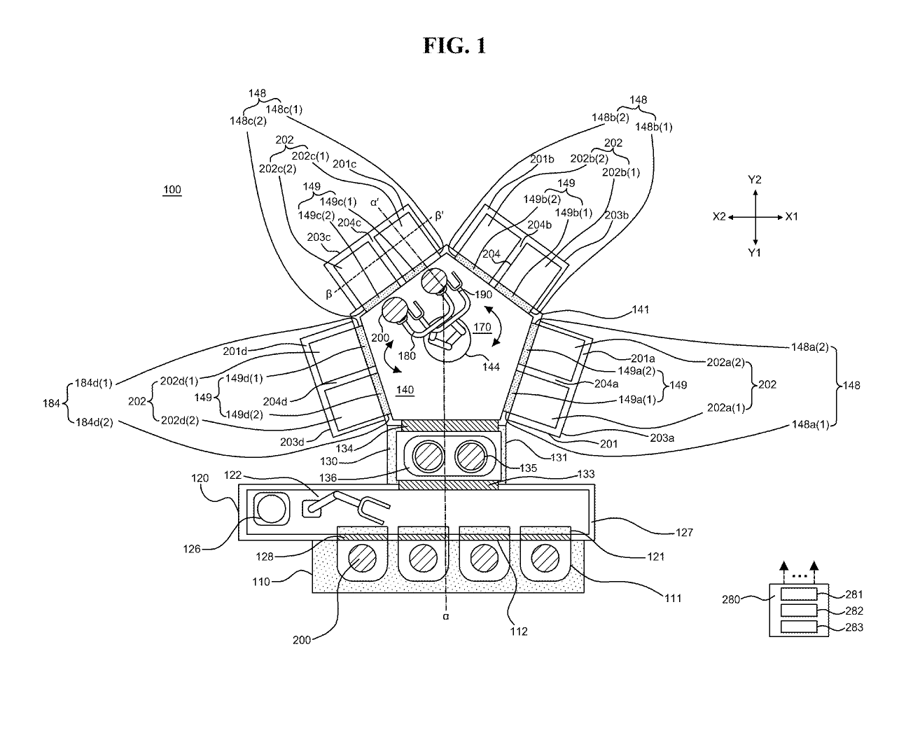

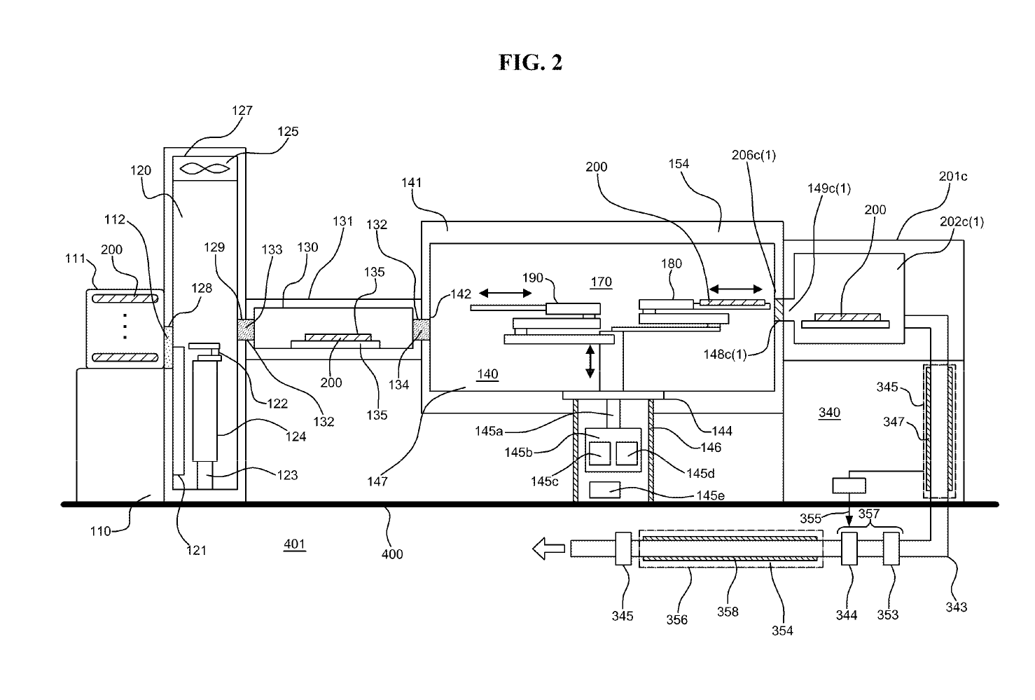

A schematic configuration of a substrate processing apparatus according to an embodiment of the present invention will be described with reference to FIGS. 1 and 2. FIG. 1 is a cross-sectional view exemplifying a substrate processing apparatus according to the present embodiment. FIG. 2 is a vertical cross-sectional view of the substrate processing apparatus according to the present embodiment taken along line α-α′ of FIG. 1.

A substrate processing apparatus 100 to which the present invention illustrated in FIGS. 1 and 2 is applied processes a wafer 200 serving as a substrate and includes an IO stage 110, an atmospheric transfer chamber 120, a load lock chamber 130, a vacuum transfer chamber 140 and a module 201. The components will be described in detail below. In FIG. 1, an X1 direction indicates the right, an X2 direction indicates the left, a Y1 direction indicates the front and a Y2 direction indicates the rear.

(Atmospheric Transfer Chamber and IO Stage)

The IO stage 110 (a loading port) is installed in front of the substrate processing apparatus 100. A pod 111 is placed on the IO stage 110. Each pod 111 is used as a carrier for transferring the wafer 200 such as a silicon (Si) substrate. The unprocessed wafer 200 or the processed wafer 200 is horizontally stored in the pod 111.

A cap 112 is installed at the pod 111 and is opened and closed by a pod opener 121. The pod opener 121 opens or closes a substrate opening by opening and closing the cap 112 of the pod 111 placed on the IO stage 110. Therefore, the wafer 200 can be loaded into the pod 111 or unloaded from the pod 111. The pod 111 is placed on the IO stage 110 or unloaded from the IO stage 110 by automated material handling systems ((AMHS), an automatic wafer transfer system) (not illustrated).

The IO stage 110 is disposed adjacent to the atmospheric transfer chamber 120. The load lock chamber 130 to be described below is connected to a side different from the side of the atmospheric transfer chamber 120 to which the IO stage 110 is connected.

An atmospheric transfer robot 122 configured to transfer the wafer 200 is installed in the atmospheric transfer chamber 120. As illustrated in FIG. 2, the atmospheric transfer robot 122 is lifted by an elevator 123 installed in the atmospheric transfer chamber 120 and is moved in a left and right direction by a linear actuator 124.

A clean unit 125 configured to supply clean air is installed above the atmospheric transfer chamber 120. A notch formed in the wafer 200 or a device 126 (hereinafter referred to as a “prealigner”) configured to align an orientation flat is installed on the left of the atmospheric transfer chamber 120.

A substrate loading/unloading port 128 for loading the wafer 200 into the atmospheric transfer chamber 120 or unloading the wafer 200 from the atmospheric transfer chamber 120 and the pod opener 121 are installed on the front side of a housing 127 of the atmospheric transfer chamber 120. The IO stage 110 (a loading port) is installed at a side opposite to the pod opener 121, that is, outside the housing 127, through the substrate loading/unloading port 128.

A substrate loading/unloading port 129 for loading the wafer 200 into the load lock chamber 130 or unloading the wafer 200 from the load lock chamber 130 is installed behind the housing 127 of the atmospheric transfer chamber 120. By opening or closing the substrate loading/unloading port 129 using a gate valve 133, the wafer 200 can be loaded into the load lock chamber 130 or unloaded from the load lock chamber 130 through the substrate loading/unloading port 129.

(Load Lock Chamber)

The load lock chamber 130 is disposed adjacent to the atmospheric transfer chamber 120. As will be described below, the vacuum transfer chamber 140 is disposed on a side different from a side on which the atmospheric transfer chamber 120 is disposed among sides of a housing 131 of the load lock chamber 130. Since a pressure in the housing 131 is changed according to a pressure of the atmospheric transfer chamber 120 and a pressure of the vacuum transfer chamber 140, the load lock chamber 130 has a structure that can withstand a negative pressure.

A substrate loading/unloading port 132 is installed at a side adjacent to the vacuum transfer chamber 140 within the housing 131. By opening or closing the substrate loading/unloading port 132 using a gate valve 134, the wafer 200 can be loaded and unloaded through the substrate loading/unloading port 132.

Also, a substrate placing table 136 including at least two placing surfaces 135 on which the wafer 200 is placed is installed in the load lock chamber 130. A distance between the substrate placing surfaces 135 is set according to a distance between end effectors included in an arm of a robot 170 (to be described below).

(Vacuum Transfer Chamber)

The substrate processing apparatus 100 includes the vacuum transfer chamber 140, which is a transfer space through which the wafer 200 is transferred a under negative pressure. A housing 141 of the vacuum transfer chamber 140 may be formed in a pentagon shape as seen in a birds-eye view. The load lock chamber 130 and modules 201a, 201b, 201c and 201d configured to process the wafer 200 are connected to sides of the pentagon. The robot 170 configured to transfer the wafer 200 under a negative pressure is installed at a substantially central part of the vacuum transfer chamber 140 using a flange 144 as a base.

A substrate loading/unloading port 142 is installed at a sidewall adjacent to the load lock chamber 130 among sidewalls of the housing 141. By opening or closing the substrate loading/unloading port 142 using the gate valve 134, the wafer 200 can be loaded and unloaded through the substrate loading/unloading port 142.

The vacuum transfer robot 170 installed in the vacuum transfer chamber 140 can be lifted while maintaining airtightness of the vacuum transfer chamber 140 by a shaft 145 and the flange 144.

A support shaft 145a configured to support a shaft of the vacuum transfer robot 170 and the actuation unit 145b configured to lift or rotate the support shaft 145a are installed in the shaft 145. An actuation unit 145b includes a lifting mechanism 145c including a motor configured to implement lifting and a rotating mechanism 145d such as a gear configured to rotate the support shaft 145a. Also, an instruction unit 145e configured to instruct the actuation unit 145b to lift or rotate may be installed in the shaft 145.

The lifting mechanism 145c includes a motor in which a lubricant such as grease is included. Also, the rotating mechanism 145d includes a plurality of gears in which a lubricant such as grease is applied therebetween. The instruction unit 145e includes a precision instrument such as a semiconductor chip. When a thermal load is applied, since grease is consumed or hardened, malfunctioning of the lifting mechanism 145c or the rotating mechanism 145d is caused. Also, when the thermal load is applied, failure is caused in the semiconductor chip of the instruction unit 145e. Therefore, the vicinity of the shaft 145 is surrounded by a first thermal reduction structure 146, and an influence by heat from a gas box (to be described in detail below), etc. disposed nearby is reduced. The first thermal reduction structure 146 has the same cylindrical shape as an outer circumference of the shaft 145 to be in close contact with the shaft 145. By surrounding the outer circumference of the shaft 145 by the first thermal reduction structure 146, it is possible to uniformly reduce an influence by heat from the radially disposed gas box.

As illustrated in FIG. 1, the modules 201a, 201b, 201c and 201d (process modules) configured to perform a desired process on the wafer 200 are connected to sidewalls at which the load lock chamber 130 is not installed among the five sidewalls of the housing 141.

A chamber 202 is installed in the modules 201a, 201b, 201c and 201d. Specifically, chambers 202a(1) and 202a(2) are installed in the module 201a. Chambers 202b(1) and 202b(2) are installed in the module 201b. Chambers 202c(1) and 202c(2) are installed in the module 201c. Chambers 202d(1) and 202d(2) are installed in the module 201d.

A partition wall 204 is installed between two chambers 202 installed in the module 201 so that an atmosphere of a processing space 205 (to be described below) is not mixed. Therefore, each chamber can have an independent atmosphere.

A substrate loading/unloading port 148 is installed at a sidewall facing each chamber among sidewalls of the housing 141. For example, as illustrated in FIG. 2, a substrate loading/unloading port 148c(1) is installed at a sidewall of the housing 141 adjacent to the chamber 202c(1).

As illustrated in FIG. 1, a substrate loading/unloading port 148a(1) is installed at a sidewall of the housing 141 adjacent to the chamber 202a(1).

Similarly, a substrate loading/unloading port 148a(2) is installed at a sidewall of the housing 141 adjacent to the chamber 202a(2).

Similarly, a substrate loading/unloading port 148b(1) is installed at a sidewall of the adjacent housing 141 facing the chamber 202b(1).

Similarly, a substrate loading/unloading port 148b(2) is installed at a sidewall of the housing 141 adjacent to the chamber 202b(2).

Similarly, a substrate loading/unloading port 148c(2) is installed at a sidewall of the housing 141 adjacent to the chamber 202c(2).

Similarly, a substrate loading/unloading port 148d(1) is installed at a sidewall of the housing 141 adjacent to the chamber 202d(1).

Similarly, a substrate loading/unloading port 148d(2) is installed at a sidewall of the housing 141 adjacent to the chamber 202d(2).

As illustrated in FIG. 1, a gate valve 149 is installed at the chamber 202. Specifically, a gate valve 149a(1) and a gate valve 149a(2) are installed at the chamber 202a(1) and the chamber 202a(2), respectively. A gate valve 149b(1) and a gate valve 149b(2) are installed at the chamber 202b(1) and the chamber 202b(2), respectively. A gate valve 149c(1) and a gate valve 149c(2) are installed at the chamber 202c(1) and the chamber 202c(2), respectively. A gate valve 149d(1) and a gate valve 149d(2) are installed at the chamber 202d(1) and the chamber 202d(2), respectively.

By opening or closing the substrate loading/unloading port 148 using each gate valve 149, the wafer 200 can be loaded and unloaded through the substrate loading/unloading port 148.

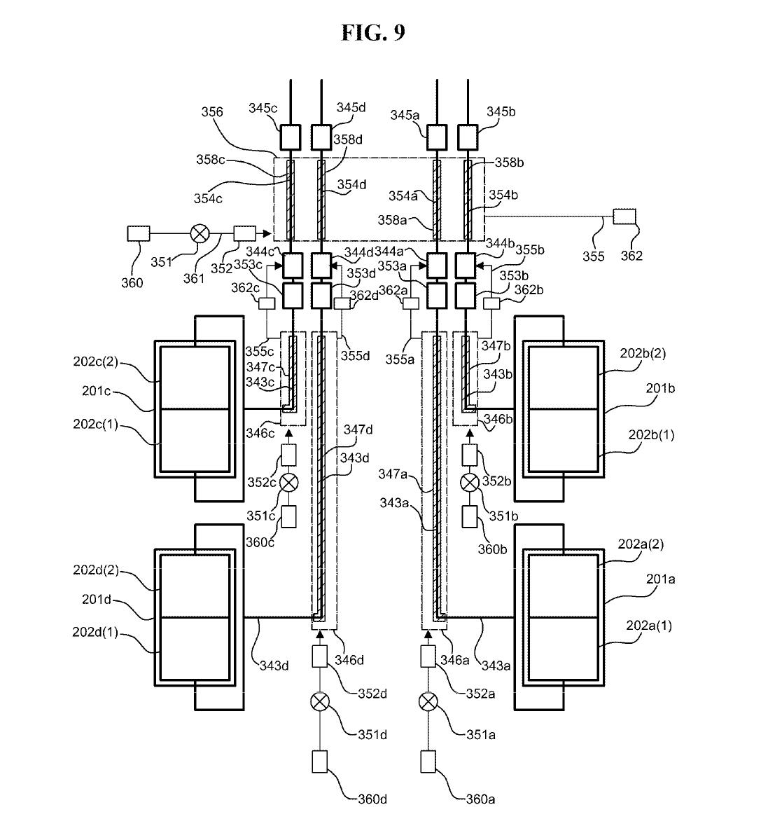

An exhaust pipe 343 will be described with reference to FIGS. 2, 5 and 9. FIG. 9 is an explanatory diagram describing a gas exhaust path according to the present embodiment.

The first exhaust pipe 343 is installed at the chamber 202c(1) in the module 201c. A gas box 340 is disposed below the module 201c. A second thermal reduction structure 346 including a room forming a vacuum space therein, a main part of the first exhaust pipe 343 and a heater 347 configured to heat the first exhaust pipe 343 are accommodated in the gas box 340.

The substrate processing apparatus 100 is installed in a building and is disposed on a building floor 400. The first exhaust pipe 343 is connected to a mass flow controller 353 and a pump 344 (collectively referred to as an exhaust control unit 357) in a maintenance area disposed below the building floor 400 through the gas box 340. That is, the first exhaust pipe 343 includes one end that is connected to the chamber 202c(1) and the other end that is connected to the exhaust control unit 357. A main part between one end and the other end of the first exhaust pipe 343 is disposed below the above-described processing chamber 202c(1). A second exhaust pipe 354 is connected to the downstream side of the pump 344. An exhaust pipe 354a communicates with the module 201a. An exhaust pipe 354b communicates with the module 201b. An exhaust pipe 354c communicates with the module 201c. An exhaust pipe 354d communicates with the module 201d. The exhaust pipe 354a, the exhaust pipe 354b, the exhaust pipe 354c and the exhaust pipe 354d are collectively referred to as the second exhaust pipe 354.

In view of instrument disposition efficiency in a cleanroom in which the substrate processing apparatus 100 is placed, an exhaust system instrument is disposed in one location. Therefore, all of the exhaust pipe 354a, the exhaust pipe 354b, the exhaust pipe 354c and the exhaust pipe 354d are disposed toward one location. In particular, since there is a risk of increasing deposits when an exhaust pipe becomes longer, it is preferable that the exhaust pipe 354a, the exhaust pipe 354b, the exhaust pipe 354c and the exhaust pipe 354d connected to the exhaust system in the cleanroom be as short as possible. According to such conditions, the exhaust pipe 354a, the exhaust pipe 354b, the exhaust pipe 354c and the exhaust pipe 354d are preferably disposed adjacently. When the exhaust pipe 354a, the exhaust pipe 354b, the exhaust pipe 354c and the exhaust pipe 354d are disposed adjacently, a footprint is prevented from being large.

A heater 358 configured to heat the second exhaust pipe 354 is installed at the second exhaust pipe 354. Specifically, a heater 358a, a heater 358b, a heater 358c and a heater 358d are installed at the exhaust pipe 354a, the exhaust pipe 354b, the exhaust pipe 354c and the exhaust pipe 354d, respectively.

As described above, since the exhaust pipe 354a, the exhaust pipe 354b, the exhaust pipe 354c and the exhaust pipe 354d are disposed adjacently, the heater 358a, the heater 358b, the heater 358c and the heater 358d are also disposed adjacently. When the heater 358a, the heater 358b, the heater 358c and the heater 358d are disposed adjacently, since the vicinity thereof is in a high temperature state, the exhaust pipe 354a, the exhaust pipe 354b, the exhaust pipe 354c and the exhaust pipe 354d are installed in a third thermal reduction structure 356 including a room forming a vacuum space therein. In such a configuration, it is possible to form the compact substrate processing apparatus 100. A harm removing device 345 which is an exhaust gas processing device is installed at the downstream side of each second exhaust pipe 354, and can discharge an exhaust gas to the outside (not illustrated).

The heater 347 configured to heat the first exhaust pipe 343 at a temperature higher than a liquefaction temperature at which a source gas which is a first gas is liquefied under vapor pressure. Since the heater 358 configured to heat the second exhaust pipe 354 is installed at the downstream side of the pump 344, it can heat the second exhaust pipe 354 to a temperature higher than that of the heater 347, as will be described below.

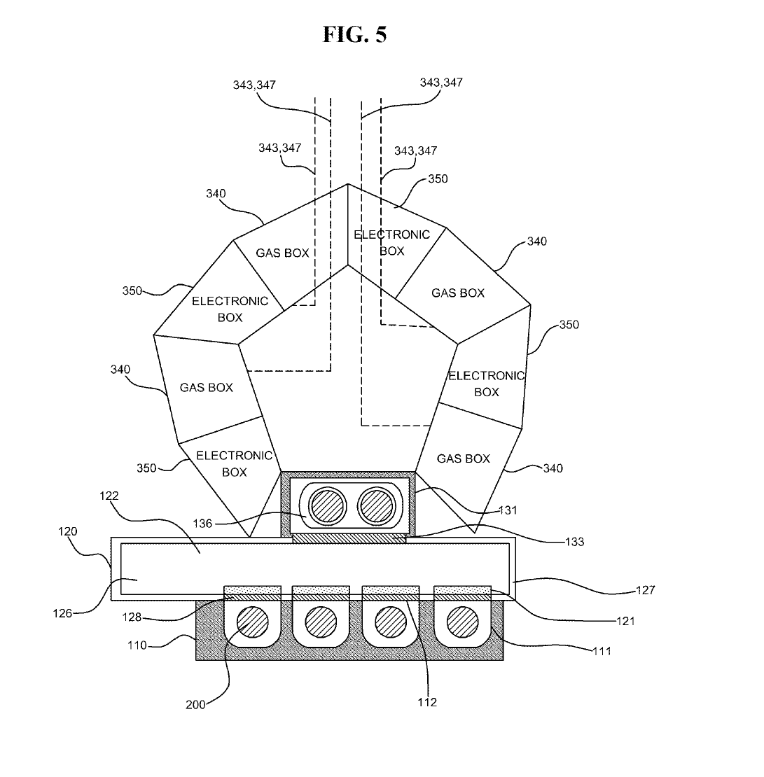

Thereafter, the gas box 340 and an electronic box 350 disposed below the modules 201a, 201b, 201c and 201d will be described with reference to FIG. 5 is a plan view of a cluster device. Also, for easily understanding dispositions of the gas box 340 and the electronic box 350, the modules 201a, 201b, 201c and 201d are not illustrated in FIG. 5.

The gas box 340 configured to supply a gas to each chamber or exhaust a gas from each chamber and the electronic box 350 in which an electronic device configured to control an operation of each module is embedded are installed below the modules 201a, 201b, 201c and 201d. A gas supply pipe, a gas exhaust pipe and the like are accommodated in the gas box 340. Electronic devices such as a semiconductor chip having a low thermal resistance is accommodated in the electronic box 350. In view of component disposition efficiency, the gas box 340 and the electronic box 350 are disposed adjacent to each other. As will be described below, the exhaust pipe installed in the gas box 340 is thermally controlled by the heater 347 to be at a temperature higher than a liquefaction temperature at which a gas is liquefied under vapor pressure. However, since the electronic box 350 in which a control unit configured as an electrical component having low thermal resistance or the like is accommodated is disposed adjacent to the gas box 340, an insulating material is installed near the heater 347 of the exhaust pipe in the gas box 340. A thermal reduction structure (to be described below) including a room forming a vacuum space therein is installed as, for example, an insulating material. An atmosphere control unit (to be described below) which is a gas supply and exhaust mechanism is installed in the thermal reduction structure. The atmosphere control unit can control an internal atmosphere of the thermal reduction structure.

The first exhaust pipe 343 extended from the gas box is indicated by a dotted line and extends along a maintenance area 401 below the vacuum transfer chamber 140. As a result, as will be described below, “a sum of volumes of an gas exhaust pipe 341, a gas exhaust pipe 342 and the gas exhaust pipe 343” becomes greater than “a sum of a volume of the processing space 205 of the chamber 202c(1) and a volume of the processing space 205 of the chamber 202c(2).”

(Module)

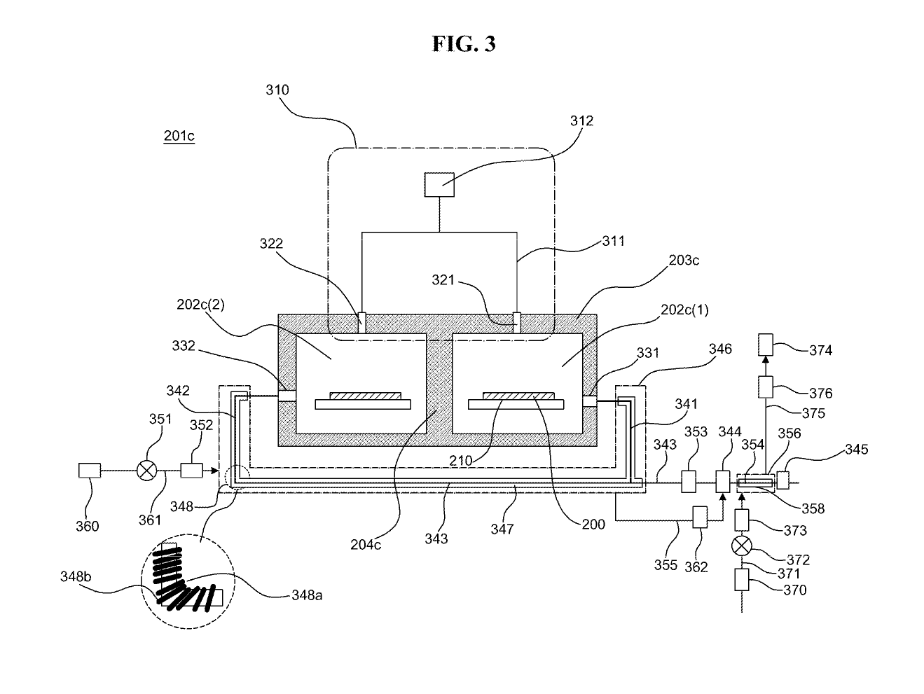

Next, the module 201 will be described with reference to FIGS. 1, 2 and 3. FIG. 3 is a cross sectional view of FIG. 1 taken along line β-β′ and is a diagram describing the module 201 and a relation between a gas supply unit and a gas exhaust unit of the module 201.

The module 201 includes a housing 203. Specifically, the module 201a, the module 201b, the module 201c and the module 201d include a housing 203a, a housing 203b, a housing 203c and a housing 203d, respectively.

The substrate loading/unloading port 148a(1) is installed at a sidewall adjacent to the vacuum transfer chamber 140 among sidewalls of the chamber 202a(1). Similarly, the substrate loading/unloading port 148a(2) is installed at a sidewall adjacent to the vacuum transfer chamber 140 among sidewalls of the chamber 202a(2). The substrate loading/unloading port 148b(1) is installed at a sidewall adjacent to the vacuum transfer chamber 140 among sidewalls of the chamber 202b(1). The substrate loading/unloading port 148b(2) is installed at a sidewall adjacent to the vacuum transfer chamber 140 among sidewalls of the chamber 202b(2). The substrate loading/unloading port 148c(1) is installed at a sidewall adjacent to the vacuum transfer chamber 140 among sidewalls of the chamber 202c(1). The substrate loading/unloading port 148c(2) is installed at a sidewall adjacent to the vacuum transfer chamber 140 among sidewalls of the chamber 202c(2). The substrate loading/unloading port 148d(1) is installed at a sidewall adjacent to the vacuum transfer chamber 140 among sidewalls of the chamber 202d(1). The substrate loading/unloading port 148d(2) is installed at a sidewall adjacent to the vacuum transfer chamber 140 among sidewalls of the chamber 202d(2).

A specific structure of modules will be described below using the module 201c as an example with reference to FIGS. 3 and 9. Since the other module 201a, module 201b and module 201d have the same structure as the module 201c, descriptions thereof will be omitted herein.

As illustrated in FIG. 3, the chamber 202c(1) and the chamber 202c(2) configured to process the wafer 200 are installed in the housing 203c. A partition wall 204c is installed between the chamber 202c(1) and the chamber 202c(2). Therefore, an atmosphere in the chamber 202c(1) and an atmosphere in the chamber 202c(2) are isolated.

A substrate support 210 configured to support the wafer 200 is installed inside the chamber 202.

A gas supply unit 310 configured to supply a processing gas to the chamber 202c(1) and the chamber 202c(2) is installed in the module 201c. The gas supply unit 310 includes a gas supply pipe 311. As will be described below, a gas supply source, a mass flow controller and a valve are installed at the gas supply pipe 311 from the upstream side to the downstream side thereof. In FIG. 3, the gas supply pipe, the mass flow controller and the valve are collectively referred to as a gas supply structure 312.

The gas supply pipe 311 is divided into two at the downstream side of the valve (the gas supply structure 312), and leading ends are connected to a gas supply hole 321 of the chamber 202c(1) and a gas supply hole 322 of the chamber 202c(2).

In the module 201c, the gas box 340 in which a gas exhaust unit configured to exhaust a gas from the chamber 202c(1) and the chamber 202c(2) is accommodated is installed. The gas exhaust unit includes the exhaust pipe 341 connected to an exhaust hole 331 of the chamber 202c(1), the exhaust pipe 342 connected to an exhaust hole 332 of the chamber 202c(2), and the first exhaust pipe 343 to which the exhaust pipe 341 and the exhaust pipe 342 are connected. The mass flow controller 353 as a pressure regulator and the pump 344 are installed at the first exhaust pipe 343 from the upstream side to the downstream side thereof. The mass flow controller 353 and the pump 344 regulate an internal pressure of each chamber with the cooperation of the gas supply unit 310. The exhaust pipe 341, the exhaust pipe 342 and the first exhaust pipe 343 are partially surrounded by the second thermal reduction structure 346. A pipe 361 whose upstream side is connected to an inert gas source 360 is connected to the second thermal reduction structure 346. A valve 351 and a mass flow controller 352 are installed at the pipe 361. Similarly, a third exhaust pipe 355 communicating with the pump 344 is connected to the second thermal reduction structure 346. An auto pressure controller (APC) 362 is installed at the third exhaust pipe 355. An atmosphere in the second thermal reduction structure 346 can remain in a vacuum state with the cooperation of the valve 351, the mass flow controller 352, the third exhaust pipe 355, the APC 362 and the pump 344. When a maintenance such as exchanging the heater 347 is performed, it is possible to restore the inside of a space to a normal atmospheric pressure by a cooperative tasking of the valve 351, the mass flow controller 352, the pipe 361 and the APC 362 of an inert gas supply unit. The valve 351, the mass flow controller 352, the pipe 361, the third exhaust pipe 355, the APC 362 and the pump 344 are collectively referred to as an atmosphere control unit. As illustrated in FIG. 3, a part of the first exhaust pipe 343 has an elbow shape 348 as circled by a dotted line, and the first thermal reduction structure surrounds at least the elbow shape 348.

A resistive heater may be installed in the elbow shape 348. In the resistive heater, for example, a heating wire is wound on the elbow shape 348. As illustrated in an enlarged view of the elbow shape 348 of FIG. 3, at an inner corner 348a of a bent position, a heating wire is dense. At an outer corner 348b of the bent position, a heating wire is sparse.

Under an atmosphere, while heat spreads due to thermal conduction at the outer corner 348b in which a heating wire is sparse, heat is concentrated at the inner corner 348a in which a heating wire is dense. Therefore, the inner corner 348a in which a heating wire is dense has a high temperature. Accordingly, the temperature may become non-uniform depending on a location even in one pipe. Meanwhile, since a gas remains in the elbow shape 348, deposits are likely to be accumulated. In order to prevent such a problem, when the outer corner 348b in which a heating wire is sparse is set to a temperature at which deposits do not adhere, a temperature of the inner corner 348a in which a heating wire is dense may significantly increase. Therefore, an insulation structure of the related art is hard to adopt setting the outer corner 348b in which a heating wire is sparse to the temperature at which deposits do not adhere. Accordingly, the present embodiment adopts a structure in which the elbow shape 348 is surrounded as the second thermal reduction structure 346 as described above. In such a structure, for example, a vacuum structure, it is possible to prevent heat from spreading through the outer corner 348b in which a heating wire is sparse and reduce a temperature difference between the inner corner 348a in which a heating wire is dense and the outer corner 348b in which a heating wire is sparse. Therefore, collection of deposits in the exhaust pipe having an elbow shape becomes harder than that under an atmosphere.

The second exhaust pipe 354 is installed at the downstream side of the pump 344 and is connected to the harm removing device 345. The heater 358 is installed at the second exhaust pipe 354. Also, the second exhaust pipe 354 and the heater 358 are surrounded by the third thermal reduction structure 356. An inside of the third thermal reduction structure 356 remains in a vacuum state. When the inside of the third thermal reduction structure 356 remains in a vacuum state, an influence of heat of the heater 358 on the outside decreases.

A pipe 371 whose upstream side is connected to an inert gas source 370 is connected to the third thermal reduction structure 356. A valve 372 and a mass flow controller 373 are installed at the pipe 371. Similarly, an exhaust pipe 375 communicating with a pump 374 is connected to the third thermal reduction structure 356. An APC 376 is installed at the exhaust pipe 375. It is possible to maintain the inside of the third thermal reduction structure 356 in a vacuum state with the cooperation of the valve 372, the mass flow controller 373, the pipe 371, the APC 376 and the pump 374.

Also, when a maintenance such as exchanging the heater 358 is performed, it is possible to restore an inside of a space by a cooperative tasking of the valve 372, the mass flow controller 373, the pipe 371, the exhaust pipe 375, the APC 376 and the pump 374 of an inert gas supply unit. The valve 372, the mass flow controller 373, the pipe 371, the exhaust pipe 375, the APC 376 and the pump 374 are collectively referred to as an atmosphere control unit.

FIG. 9 illustrates the substrate processing apparatus including the modules 201a, 201b, 201c and 201d. For example, exhaust pipes connected to the module 201a are denoted by reference numerals 343a, 355a and 358a. Heat reduction structures are denoted by reference numerals 346a and 356. Exhaust pipes connected to the module 201b are denoted by reference numerals 343b, 355b and 358b. Heat reduction structures are denoted by reference numerals 346b and 356. Exhaust pipes connected to the module 201c are denoted by reference numerals 343c, 355c and 358c. Heat reduction structures are denoted by reference numerals 346c and 356. Exhaust pipes connected to the module 201d are denoted by reference numerals 343d, 355d and 358d. Heat reduction structures are denoted by reference numerals 346d and 356. Since operations and functions of respective components are the same as those of the exhaust pipes 343, 355 and 358, and the thermal reduction structures 346 and 356 of FIG. 3 described above, details thereof will be omitted.

(Chamber)

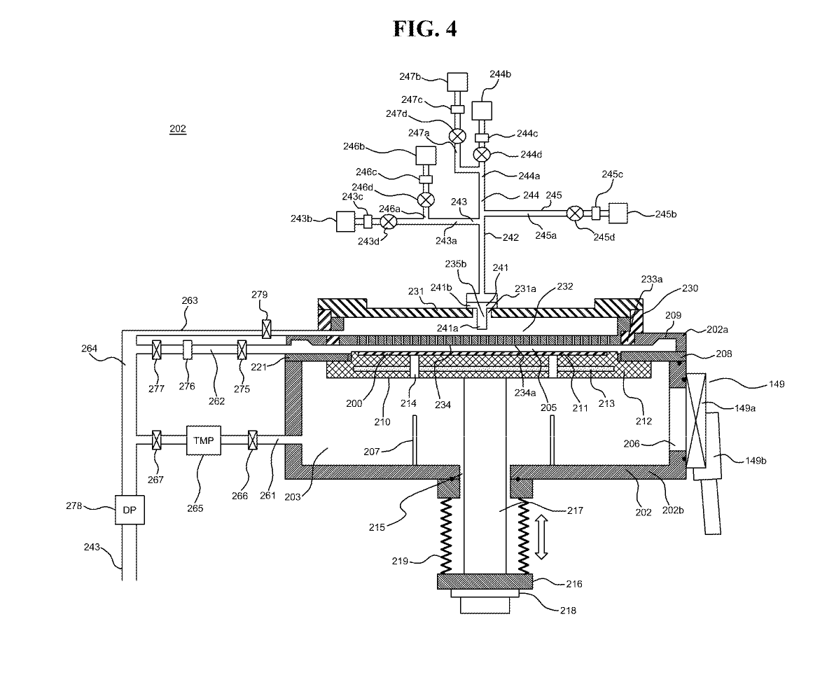

Next, the chamber 202 and a structure in the vicinity thereof will be described with reference to FIG. 4. As illustrated in FIG. 1 or 3, the chamber 202 includes an adjacent chamber, but the adjacent chamber will not be described herein for simplicity of description.

The module 201 includes the chamber 202 illustrated in FIG. 4. The chamber 202 is, for example, a flat sealed container having a circular cross section. Also, the chamber 202 is made of a metallic material such as aluminum (Al) or a stainless steel (SUS). In the chamber 202, the processing space 205 in which the wafer 200 such as a silicon substrate is processed and the transfer space 303 through which the wafer 200 passes when the wafer 200 is transferred into the processing space 205 are provided. The chamber 202 includes an upper container 202a and a lower container 202b. A partition plate 208 is installed between the upper container 202a and the lower container 202b.

The substrate loading/unloading port 148 adjacent to the gate valve 149 is installed at a side of the lower container 202b. The wafer 200 moves between transfer chambers (not illustrated) through the substrate loading/unloading port 148. Lift pins 207 are installed at a bottom of the lower container 202b. Also, the lower container 202b is grounded.

The gate valve 149 includes a valve body 149a and a driving body 149b. The valve body 149a is fixed to a part of the driving body 149b. When the gate valve 149 is open, the driving body 149b is isolated from the chamber 202, and the valve body 149a is separated from a sidewall of the chamber 202. When the gate valve is closed, the driving body 149b moves toward the chamber 202, and the valve body 149a presses the sidewall of the chamber 202 to close the gate valve.

The substrate support 210 configured to support the wafer 200 is installed in the processing space 205. The substrate support 210 includes a substrate placing table 212 having a placing surface 211 on which the wafer 200 is placed and a heater 213 as a heating source contained in the substrate placing table 212. Through-holes 214 through which the lift pins 207 penetrate are provided at positions corresponding to the lift pins 207 of the substrate placing table 212.

The substrate placing table 212 is supported by a shaft 217. A support of the shaft 217 penetrates through a hole 215 installed at a bottom wall of the chamber 202 and is connected to a lifting mechanism 218 outside the chamber 202 through a support plate 216. When the lifting mechanism 218 is operated to lift the shaft 217 and the substrate placing table 212, the wafer 200 placed on the substrate placing surface 211 is lifted. Also, the vicinity of a lower end of the shaft 217 is covered by a bellows 219. An inside of the chamber 202 remains in an airtight state.

When the wafer 200 is transferred, the substrate placing surface 211 of the substrate placing table 212 is lowered to reach a position (wafer transfer position) corresponding to the substrate loading/unloading port 148. When the wafer 200 is processed, as illustrated in FIG. 4, the substrate placing surface 211 is raised such that the wafer 200 reaches a processing position (a wafer processing position) in the processing space 205.

Specifically, when the substrate placing table 212 is lowered to reach the wafer transfer position, upper ends of the lift pins 207 protrude from an upper surface of the substrate placing surface 211, and the lift pins 207 support the wafer 200 from underneath. On the other hand, when the substrate placing table 212 is raised to reach the wafer processing position, the lift pins 207 are buried below the upper surface of the substrate placing surface 211, and the substrate placing surface 211 may support the wafer 200 from thereunder. Also, since the lift pins 207 are in contact directly with the wafer 200, the lift pins 207 are preferably formed of a material such as quartz or alumina.

A shower head 240 serving as a gas dispersion mechanism is installed at an upstream side of the processing space 205. The gas inlet hole 231a into which a first dispersion mechanism 241 is inserted is installed at a lid 231 of the shower head 240. The first dispersion mechanism 241 includes a distal end portion 241a inserted into the shower head and a flange 241b fixed to the lid 231.

The distal end portion 241a has a columnar or cylindrical shape. A dispersion hole is installed at a side of a cylinder. A gas supplied through a gas supply unit (a supply system) of a chamber to be described below is supplied to a buffer space 232 through the distal end portion 241a.

The shower head 240 includes a dispersion plate 234 which is a second dispersion mechanism configured to disperse a gas. An upstream side space of the dispersion plate 234 is the buffer space 232, and a downstream side space is the processing space 205. The dispersion plate 234 includes a plurality of through-holes 234a. The dispersion plate 234 is disposed to face the substrate placing surface 211.

The dispersion plate 234 has, for example, a disk shape. The through-hole 234a is disposed over the entire surface of the dispersion plate 234. The adjacent through-holes 234a may be disposed at equal distances. The through-hole 234a disposed outermost is disposed outer than an outer circumference of the wafer placed on the substrate placing table 212.

The upper container 202a includes a flange and a support block 230 is fixedly placed on the flange. The support block 230 includes a flange 233a, and the dispersion plate 234 is fixedly placed on the flange 233a. Also, the lid 231 is fixed to a top surface of the support block 230. In such a structure, it is possible to remove the lid 231, the dispersion plate 234 and the support block 230 in order from the top.

(Supply Unit)

A supply unit of the chamber 202 described herein has the same configuration as the gas supply unit 310 of FIG. 3. A configuration corresponding to each chamber will be described in further detail.

The first dispersion mechanism 241 of the chamber is connected to the gas inlet hole 231a (corresponds to the gas supply hole 321 or 322 in FIG. 3) installed at the lid 231 of the shower head 240. A common gas supply pipe 242 is connected to the first dispersion mechanism 241. The first dispersion mechanism and the common gas supply pipe 242 correspond to the gas supply pipe 311 of FIG. 3.

A flange is installed at the first dispersion mechanism 241, and the flange installed at the first dispersion mechanism 241 is fixed at the lid 231 or the flange of the common gas supply pipe 242 by a screw.

The first dispersion mechanism 241 communicates with the common gas supply pipe 242. A gas supplied through the common gas supply pipe 242 is supplied to the shower head 240 through the first dispersion mechanism 241 and the gas inlet hole 231a.

A first gas supply pipe 243a, a second gas supply pipe 244a and a third gas supply pipe 245a are connected to the common gas supply pipe 242.

A gas containing a first element (hereinafter referred to as a “first element-containing gas”) is supplied mainly through a first gas supply system 243 including the first gas supply pipe 243a. A second element-containing gas is supplied mainly through a second gas supply system 244 including the second gas supply pipe 244a.

(First Gas Supply System of Chamber)

A first gas supply source 243b, a mass flow controller 243c serving as a flow rate controller (a flow rate control unit) and a valve 243d serving as an on-off valve are installed in order at the first gas supply pipe 243a from the upstream side to the downstream side thereof

The first element-containing gas is supplied to the shower head 240 through the mass flow controller 243c and the valve 243d installed at the first gas supply pipe 243a, and the common gas supply pipe 242.

The first element-containing gas is a gas containing a halide, and is a source gas, that is, one of processing gases. Here, the first element is, for example, silicon (Si). That is, the first element-containing gas is, for example, a silicon-containing gas. Specifically, dichlorosilane (SiH₂Cl₂, referred to as DCS) gas can be used as the silicon-containing gas.

Also, the first element-containing gas may be in any of solid, liquid and gas states at room temperature and normal pressure. When the first element-containing gas is in a liquid state under room temperature and normal pressure, an evaporator (not illustrated) may be installed between the first gas supply source 243b and the mass flow controller 243c. Here, an example in which the first element-containing gas is in a gas state will be described.

The downstream end of a first inert gas supply pipe 246a is connected at the downstream side of the valve 243d installed at the first gas supply pipe 243a. An inert gas supply source 246b, a mass flow controller 246c serving as a flow rate controller, and a valve 246d serving as an on-off valve are installed in order at the first inert gas supply pipe 246a from the upstream side to the downstream side thereof.

Here, an inert gas is, for example, nitrogen (N₂) gas. Also, in addition to N₂ gas, rare gases, for example, helium (He) gas, neon (Ne) gas and argon (Ar) gas can be used as the inert gas.

The first element-containing gas supply system 243 (referred to as a “silicon-containing gas supply system”) includes the first gas supply pipe 243a, the mass flow controller 243c and the valve 243d.

Also, a first inert gas supply system includes the first inert gas supply pipe 246a, the mass flow controller 246c and the valve 246d. Also, the first inert gas supply system may further include the inert gas supply source 246b and the first gas supply pipe 243a.

Also, the first element-containing gas supply system 243 may further include the first gas supply source 243b and the first inert gas supply system.

(Second Gas Supply System of Chamber)

A second gas supply source 244b, a mass flow controller 244c serving as a flow rate controller (a flow rate control unit) and a valve 244d serving as an on-off valve are installed in order at the second gas supply pipe 244a from the upstream side to the downstream side thereof.

A gas (hereinafter referred to as a “second element-containing gas”) containing a second element serving as a second gas is supplied to the shower head 240 through the mass flow controller 244c and the valve 244d installed at the second gas supply pipe 244a and the common gas supply pipe 242.

The second element-containing gas is one of the processing gases. Also, the second element-containing gas can be considered as a reactive gas or a modifying gas.

Here, the second element-containing gas includes a second element different from the first element. The second element may be any of oxygen (O), nitrogen (N) and carbon (C). In the present embodiment, the second element-containing gas is, for example, a nitrogen-containing gas. Ammonia (NH₃) gas can be used as the nitrogen-containing gas.

The second element-containing gas supply system 244 (referred to as a nitrogen-containing gas supply system) includes the second gas supply pipe 244a, the mass flow controller 244c and the valve 244d.

Also, the downstream end of a second inert gas supply pipe 247a is connected to the downstream side of the valve 244d installed at the second gas supply pipe 244a. An inert gas supply source 247b, a mass flow controller 247c serving as a flow rate controller (a flow rate control unit) and a valve 247d serving as an on-off valve are installed in order at the second inert gas supply pipe 247a from the upstream side to the downstream side thereof.

The inert gas is supplied to the shower head 240 through the mass flow controller 247c and the valve 247d installed at the second inert gas supply pipe 247a and the second gas supply pipe 244a. The inert gas serves as a carrier gas or a dilution gas in a film-forming process (S104).

A second inert gas supply system includes the second inert gas supply pipe 247a, the mass flow controller 247c and the valve 247d. Also, the second inert gas supply system may further include the inert gas supply source 247b and the second gas supply pipe 244a.

Also, the second element-containing gas supply system 244 may further include the second gas supply source 244b and the second inert gas supply system.

(Third Gas Supply System of Chamber)

A third gas supply source 245b, a mass flow controller 245c serving as a flow rate controller (a flow rate control unit) and a valve 245d serving as an on-off valve are installed in order at the third gas supply pipe 245a from the upstream side to the downstream side thereof.

The inert gas serving as a purge gas is supplied to the shower head 240 through the mass flow controller 245c and the valve 245d installed at the third gas supply pipe 245a and the common gas supply pipe 242.

Here, the inert gas is, for example, nitrogen (N₂) gas. Also, in addition to N₂ gas, rare gases, for example, helium(He) gas, neon(Ne) gas and argon (Ar) gas can be used as the inert gas.

A third gas supply system 245 includes the third gas supply pipe 245a, the mass flow controller 245c and the valve 245d.

In a substrate processing process, the inert gas is supplied to the shower head 240 through the mass flow controller 245c and the valve 245d installed at the third gas supply pipe 245a and the common gas supply pipe 242.

In the substrate processing process, the inert gas supplied through the inert gas supply source 245b serves as the purge gas used for purging a gas remaining in the chamber 202 or the shower head 240.

(Exhaust Unit)

The exhaust unit has a structure installed at the downstream side of the exhaust holes 331 and 332 of FIG. 3. The exhaust unit configured to exhaust an atmosphere of the chamber 202 includes a plurality of exhaust pipes connected to the chamber 202. Specifically, the exhaust unit includes an exhaust pipe 263, an exhaust pipe 262 and an exhaust pipe 261 connected to the buffer space 232, the processing space 205 and the transfer space 303, respectively. Also, an exhaust pipe 264 is connected to the downstream sides of the exhaust pipes 261, 262 and 263.

The exhaust pipe 261 is connected to the transfer space 303 through a sidewall or a bottom of the transfer space 303. A pump 265 is installed at the exhaust pipe 261. A valve 266 serving as a first exhaust valve for a transfer space is installed at the upstream side of the pump 265 installed at the exhaust pipe 261.

The exhaust pipe 262 is connected to the processing space 205 through a sidewall of the processing space 205. An automatic pressure controller (APC) 276 which is a pressure controller configured to maintain an internal pressure of the processing space 205 at a predetermined pressure is installed at the exhaust pipe 262. The APC 276 includes a valve body (not illustrated) capable of regulating a degree of opening and regulates conductance of the exhaust pipe 262 according to an instruction from a controller (to be described below). A valve 275 is installed at the upstream side of the APC 276 installed at the exhaust pipe 262. The exhaust pipe 262, the valve 275 and the APC 276 are collectively referred to as a processing chamber exhaust unit.

The exhaust pipe 263 is connected to a part different from a part to which the exhaust pipe 262 is connected. For example, the exhaust pipe 263 is connected to the buffer space 232 through a sidewall of the buffer space 232. A valve 279 is provided at the exhaust pipe 263. The exhaust pipe 263 and the valve 279 are collectively referred to as a shower head exhaust unit.

A DP (dry pump) 278 is installed at the exhaust pipe 264. As illustrated, the exhaust pipe 263, the exhaust pipe 262 and the exhaust pipe 261 are connected in order at the exhaust pipe 264 from the upstream side to the downstream side thereof. Also, the DP 278 is installed at the downstream side of the exhaust pipe 264. The DP 278 exhausts an atmosphere of the buffer space 232, the processing space 205 and the transfer space 303 through the exhaust pipe 262, the exhaust pipe 263 and the exhaust pipe 261, respectively. Also, when the TMP 265 is operated, the DP 278 serves as an auxiliary pump. That is, since it is difficult for the TMP 265 which is a high vacuum (or ultra-high vacuum) pump to independently perform exhausting into an atmospheric pressure, the DP 278 is used as the auxiliary pump configured to perform exhausting to the atmospheric pressure. An air valve may be used as a valve of each of the above exhaust unit. The first exhaust pipe 343 is connected to the downstream side of the DP 278.

(Controller)

As illustrated in FIG. 1, the substrate processing apparatus 100 includes a controller 280 configured to control operations of units of the substrate processing apparatus 100. The controller 280 includes at least a calculation unit 281 and a storage unit 282. The controller 280 is connected to the above-described configurations, calls a program or a recipe from the storage unit 282 according to an instruction of a host controller or a user, and controls operations of the configurations according to the content. Also, the controller 280 may be embodied by a dedicated computer or a general-purpose computer. For example, an external storage device 283 (for example, a magnetic tape, a magnetic disk such as a flexible disk or a hard disk, an optical disc such as a CD or a DVD, a magneto-optical disc such as an MO, and a semiconductor memory such as a USB memory (a USB flash drive) or a memory card) in which the program is stored is prepared. The external storage device 283 is used to install the program in the general-purpose computer, and thus it is possible to implement the controller 280 according to the present embodiment. Also, a method of supplying the program to the computer is not limited to the external storage device 283. For example, a communication method such as the Internet or a dedicated line may be used to supply the program without the external storage device 283. Also, the storage unit 282 or the external storage device 283 may be implemented by a computer-readable recording medium. Hereinafter, these are collectively referred to as a recording medium. Also, when the term “recording medium” is used herein, it includes either or both of the storage unit 282 and the external storage device 283.

<Substrate Processing Process>

Next, a process of forming a thin film on the wafer 200 using the substrate processing apparatus 100 will be described. In the following description, operations of units of the substrate processing apparatus 100 are controlled by the controller 280.

(Transfer Process from Atmospheric Transfer Chamber to Load Lock Chamber)

For example, 25 unprocessed wafers 200 accommodated in the pod 111 are transferred into the substrate processing apparatus configured to perform a heat treatment process by an inter-process transfer device. As illustrated in FIGS. 1 and 2, the transferred pod 111 is received from the transfer device and placed on the 10 stage 110. The cap 112 of the pod 111 is removed by the pod opener 121, and a substrate opening of the pod 111 is open.

When the pod 111 is opened by the pod opener 121, the atmospheric transfer robot 122 installed in the atmospheric transfer chamber 120 picks up the wafer 200 from the pod 111 and transfers the wafer 200 into the load lock chamber 130,\ and places the wafer 200 on the substrate placing table 136. During the placement task, since the gate valve 134 between the load lock chamber 130 and the vacuum transfer chamber 140 is closed, an internal pressure of the vacuum transfer chamber 140 is maintained. The internal pressure of the vacuum transfer chamber 140 is maintained to be a pressure of a vacuum transfer mode, for example, 1 Torr.

When the two wafers 200 are placed on the substrate placing surface 135, the gate valve 133 is closed, and an inside of the load lock chamber 130 is exhausted to become a negative pressure by an exhaust device (not illustrated).

(Transfer Process from Load Lock Chamber to Vacuum Transfer Chamber)

When an inside of the load lock chamber 130 has a preset pressure value, the load lock chamber 130 and the vacuum transfer chamber 140 communicate by opening the gate valve 134. In this case, a pressure of the vacuum transfer chamber 140 remains at a pressure in a vacuum transfer mode.

Next, the robot 170 transfers the wafer 200 from the load lock chamber 130 to the vacuum transfer chamber 140. Specifically, the robot 170 uses horizontal movement, rotational movement, or lifting movement functions, picks up the two wafers 200 from the substrate placing table 136 by the arm 190 configured to transfer the unprocessed wafer 200 between arms 180 and 190 of the robot 170, and transfers the wafer 200 into the vacuum transfer chamber 140. In this case, the wafer 200 is placed on an end effector 191 and an end effector 192. After the wafers 200 are loaded into the vacuum transfer chamber 140 and the gate valve 134 is closed, when the gate valve 149c(1) and the gate valve 149c(2) are opened, the vacuum transfer chamber 140 communicates with the chamber 202c(1) and the chamber 202c(2).

Here, operations of the robot 170 according to loading of the wafer 200 into the chamber 202c(1) and the chamber 202c(2), a substrate process including heat treatment, and unloading of the wafer 200 from the chamber 202c(1) and the chamber 202c(2) will be described.

(Loading Process from Vacuum Transfer Chamber to Chamber)

First, the robot 170 loads the end effector 191 and the end effector 192 on which the wafer 200 is provided from the vacuum transfer chamber 140 into the chamber 202c(1) and the chamber 202c(2). Then, the wafer 200 is placed on the substrate placing surface 211 with the cooperation of the lift pins 207 in the chamber 202 in each of the chambers 202 and the substrate placing table 212.

After the wafer 200 is placed, the end effector 191 and the end effector 192 of the arm 190 is retracted to the outside of the chamber 202a. Next, the gate valve 149c(1) and the gate valve 149c(2) are closed. Next, in each of the chambers 202, the substrate support 210 on which the wafer 200 is placed is raised to the wafer processing position.

(Temperature-Rise and Pressure Regulating Process)

Next, a temperature-rise process and a pressure regulating process will be described. One chamber will be exemplified herein. However, the present invention is not limited thereto, and the same process is performed on the other chamber. The heater 213 embedded in the substrate placing table 212 is heated in advance. The wafer 200 is heated by the heater 213 to a substrate processing temperature ranging from room temperature to 700° C. A vacuum pump 246 and an APC valve 276 are used to set a pressure in the chamber 202a to, for example, 0.1 Pa to 300 Pa.

When the wafer 200 is heated by the heater 213 embedded in the substrate placing table 212, it takes a time to reach a desired temperature. Therefore, in order for the wafer 200 to quickly reach a high temperature, a lamp heating device (a lamp heater), which is a substrate heating body serving as a light source configured to emit infrared light may be further installed in addition to the heater 213. In the temperature-rise and pressure regulating process, as necessary, such a lamp heating device is supplementarily used, and the wafer 200 may be heated to the substrate processing temperature above 700° C.

(Film-Forming Process)

Next, an overview of the film-forming process will be described. Details will be described below. A process in one chamber will be exemplified herein. However, the same process is performed on the other chambers. After a temperature of the wafer 200 is raised to the substrate processing temperature, while maintaining the wafer 200 at the substrate processing temperature, the following substrate process with heat treatment are performed. That is, the wafer 200 is processed by showering a surface (a surface to be processed) of the wafer 200 disposed in the chamber 202a with a processing gas used for a desired process such as oxidation, nitridation, film-formation, and etching delivered through the common gas supply pipe 242 and then by opening the shower head 240.

(Unloading Process from Chamber to Vacuum Transfer Chamber)

The processed wafers 200 are unloaded from the chamber 202c(1) and the chamber 202c(2) by the arm 180. In this case, the processed wafer 200 is transferred to the outside of the chamber 202c(1) and the chamber 202c(2) by an operation performed in reverse to the loading of the wafer 200.

Specifically, when the substrate process of the wafer 200 is completed, the gate valve 149c(1) and the gate valve 149c(2) are open. Next, the substrate placing table 212 is lowered to a position to which the wafer 200 is transferred and the wafer 200 is placed on the lift pins 207. The processed wafer 200 is picked up by an end effector 181 and an end effector 182 that enter the chamber 202c(1) and the chamber 202c(2). Next, the end effector 181 and the end effector 182 are retracted, and the wafer 200 is transferred into the vacuum transfer chamber 140. After the wafer 200 is unloaded from the chamber 202c(1) and the chamber 202c(2), the gate valve 149c(1) and the gate valve 149c(2) are closed.

As described above, operations of loading the wafer 200 into the chamber 202c(1) and the chamber 202c(2), a substrate process including heat treatment and unloading of the wafer 200 from the chamber 202c(1) and the chamber 202c(2) are completed.

The arm 180 transfers the processed wafer 200 unloaded from the chamber 202c(1) into the load lock chamber 130. After the wafer 200 is placed on the substrate placing table 136 in the load lock chamber 130, the load lock chamber 130 is closed by the gate valve 134.

When the above operations are repeated, a predetermined number of wafers, for example, 25 wafers 200, are sequentially processed.

(Transfer Process from Load Lock Chamber to Atmospheric Transfer Chamber)

When the gate valve 134 is closed, an internal pressure of the load lock chamber 130 is restored to a substantially atmospheric pressure by the inert gas. When the internal pressure of the load lock chamber 130 is restored to a substantially atmospheric pressure, the gate valve 133 is opened and the cap 112 of the empty pod 111 placed on the IO stage 110 is opened by the pod opener 121.

Next, the atmospheric transfer robot 122 picks up the wafer 200 from the substrate placing table 136 in the load lock chamber 130, transfers the wafer 200 into the atmospheric transfer chamber 120, and accommodates the wafer 200 in the pod 111. When the wafer 200 is accommodated in the pod 111, the cap 112 of the pod 111 is closed by the pod opener 121. The pod 111 with the cap 112 closed is transferred by an inter-process transfer device from the IO stage 110 for the next process.

While the above operations are described using a case in which the module 201c is used as an example, the same operations are performed when the module 201a, the module 202b or the module 202d is used.

(Substrate Processing Process)

Next, a processing process of the wafer 200 loaded in each chamber will be described in detail. Here, a processing process common in the chambers will be described using the chamber 202 as an example.

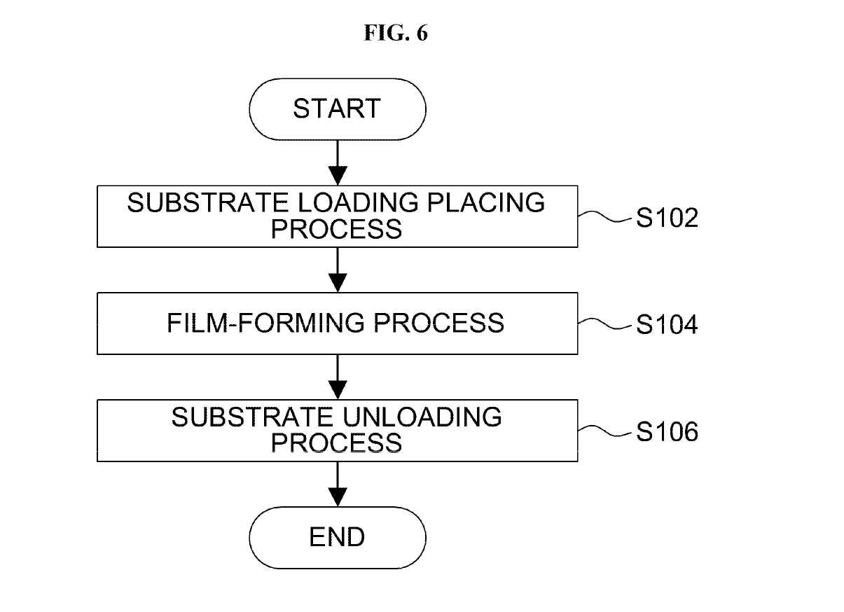

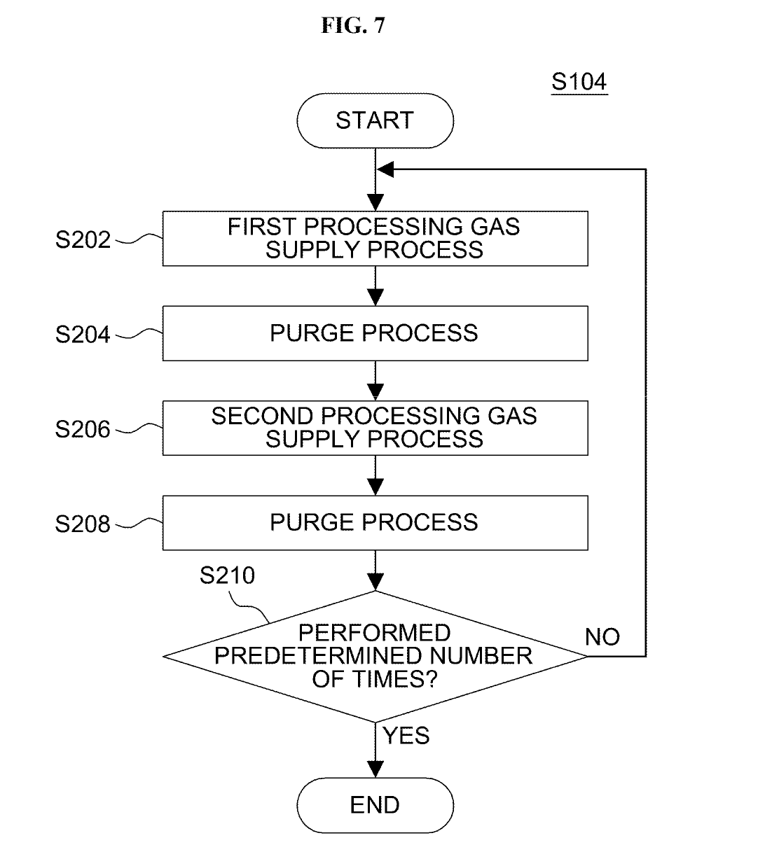

FIG. 6 is a flowchart illustrating a substrate processing process according to the present embodiment. FIG. 7 is a flowchart illustrating a film-forming process of FIG. 6 in detail.

Hereinafter, an example in which DCS gas is used as a first processing gas, ammonia (NH₃) gas is used as a second processing gas, and a silicon nitride film (a thin film) is formed on the wafer 200 will be described.

[Substrate Loading, Placing and Heating Process (S102)]

The substrate processing apparatus 100 lowers the substrate placing table 212 to the transfer position of the wafer 200, and the lift pins 207 penetrate through the through-hole 214 of the substrate placing table 212. As a result, the lift pins 207 protrude above the surface of the substrate placing table 212 by a predetermined height. Next, the gate valve 149 is opened and the transfer space 303 communicates with a transfer chamber (not illustrated). Next, a wafer transfer device (not illustrated) is used to transfer the wafer 200 from the transfer chamber into the transfer space 303, and the wafer 200 is placed on the lift pins 207. Therefore, the wafer 200 is horizontally supported on the lift pins 207 that protrude from the surface of the substrate placing table 212.

After the wafer 200 is loaded in the chamber 202, the wafer transfer device is retracted to the outside of the chamber 202, and the gate valve 149 is closed. Therefore, the chamber 202 is sealed. Next, by raising the substrate placing table 212, the wafer 200 is placed on the substrate placing surface 211 of the substrate placing table 212. By raising the substrate placing table 212, the wafer 200 is raised to a processing position (a substrate processing position) in the processing space 205.

When the wafer 200 is loaded in the transfer space 303 and then is raised to a processing position in the processing space 205, the valve 266 and a valve 267 are closed. Therefore, a gap between the transfer space 303 and the TMP 265 and a gap between the TMP 265 and the exhaust pipe 264 are blocked, and exhaust of the transfer space 303 by the TMP 265 ends. Meanwhile, by opening a valve 277 and the valve 275, the processing space 205 communicates with the APC 276, and the APC 276 communicates with the DP 278. By regulating conductance of the exhaust pipe 262, the APC 276 controls an exhaust flow rate of the processing space 205 by the DP 278, and the processing space 205 maintains in a predetermined pressure (for example, high vacuum of 10⁻⁵ Pa to 10⁻¹ Pa).

Also, in this process, while an inside of the chamber 202 is exhausted, the inert gas supply system is used to supply N₂ gas serving as the inert gas into the chamber 202. That is, while the inside of the chamber 202 is exhausted by the TMP 265 or the DP 278, by opening the valve 245d of at least the third gas supply system, it is possible to supply N₂ gas into the chamber 202.

Also, after the wafer 200 is placed on the substrate placing table 212, power is supplied to the heater 213 embedded in the substrate placing table 212 such that a surface of the wafer 200 has a predetermined temperature. The temperature of the wafer 200 ranges from, for example, room temperature to 800° C., and preferably, from room temperature to 700° C. In this case, by controlling power supply to the heater 213 based on temperature information detected by a temperature sensor (not illustrated), the temperature of the heater 213 is regulated.

[Film-Forming Process (S104)]

Next, the film-forming process (S104) will be performed. Hereinafter, the film-forming process (S104) will be described in detail with reference to FIG. 7. Also, the film-forming process (S104) includes an alternating supply process in which a process of alternately supplying different processing gases are repeated.

[First Processing Gas Supply Process (S202)]

When the wafer 200 is heated and the wafer 200 reaches a desired temperature, the valve 243d is opened and the mass flow controller 243c is regulated such that a flow rate of DCS gas has a predetermined flow rate. A flow rate of DCS gas to be supplied ranges from 100 sccm to 800 sccm. At the same time, by opening the valve 245d of the third gas supply system, N₂ gas is supplied through the third gas supply pipe 245a. N₂ gas may also be supplied using the first inert gas supply system. Before this process, N₂ gas may also be supplied through the third gas supply pipe 245a.

DCS gas supplied to the processing space 205 through the first dispersion mechanism 241 is supplied onto the wafer 200. When DCS gas comes in contact with a surface of the wafer 200, a silicon-containing layer, which is a “first element-containing layer,” is formed.

The silicon-containing layer is formed to have a predetermined thickness and a predetermined distribution according to, for example, a pressure in the chamber 202, a flow rate of DCS gas, a temperature of the substrate placing table 212, and a time for passing the processing space 205. A predetermined film may also be formed on the wafer 200 in advance. The predetermined pattern may also be formed on the wafer 200 or a predetermined film in advance.

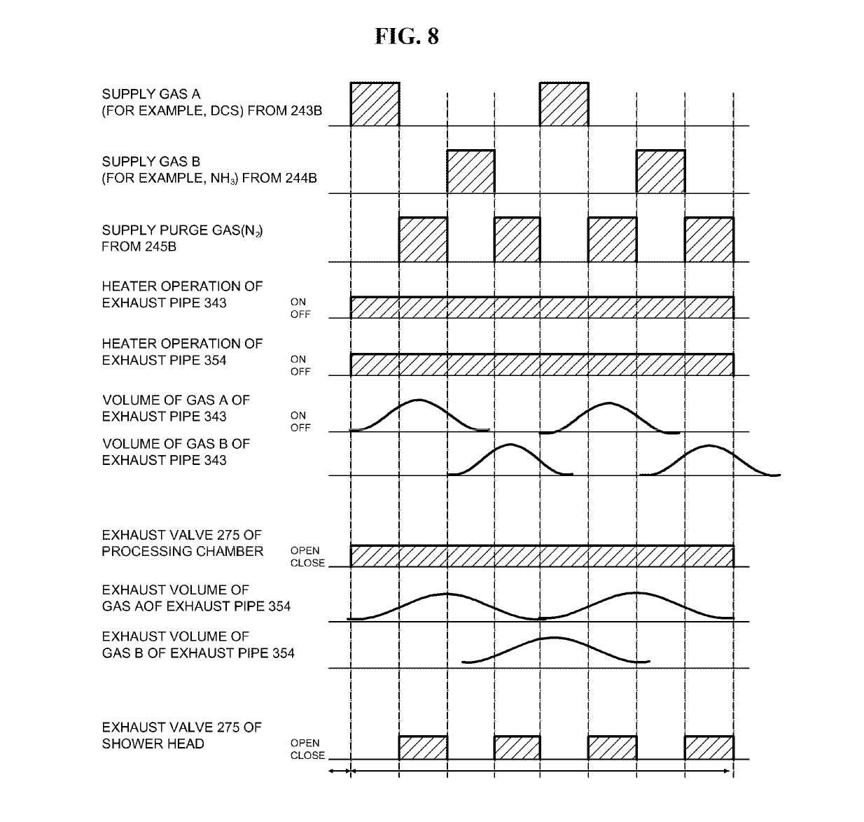

After DCS gas is supplied, when a predetermined time elapses, the valve 243d is closed to stop supply of DCS gas. As illustrated in FIG. 8, in the process (S202), the valve 275 is opened, and a pressure of the processing space 205 is regulated to a predetermined pressure by the APC 276. In the process (S202), the valves of the exhaust unit other than the valve 275 are all closed.

[Purge Process (S204)]

Then, N₂ gas is supplied through the third gas supply pipe 245a to purge the shower head 240 and the processing space 205. In this case, the valve 275 is opened, and a pressure of the processing space 205 is controlled to a predetermined pressure by the APC 276. The valves of the exhaust unit other than the valve 275 are all closed. Therefore, in the first processing gas supply process (S202), DCS gas that is not attached to the wafer 200 is removed from the processing space 205 through the exhaust pipe 262 by the DP 278.

Then, N₂ gas is supplied through the third gas supply pipe 245a to purge the shower head 240. In this case, a pressure detection unit 380 is in operation. The valve 275 is closed and the valve 279 is opened. The other valves of the exhaust unit are closed. That is, when the shower head 240 is purged, a gap between the processing space 205 and the APC 276 is blocked. By blocking the processing space 205 from the APC 276 and the APC 276 from the exhaust pipe 264, pressure control by the APC 276 is stopped, and the buffer space 232 communicates with the DP 278 at the same time. Accordingly, DCS gas remaining in the shower head 240 (the buffer space 232) is exhausted from the shower head 240 through the exhaust pipe 263 by the DP 278.

When the shower head 240 is completely purged, the valve 275 is opened and the APC 276 resumes pressure control. At the same time, by closing the valve 279, a gap between the shower head 240 and the exhaust pipe 264 is blocked. The other valves of the exhaust unit are closed. In this case, N₂ gas is continuously supplied through the third gas supply pipe 245a to purge the shower head 240 and the processing space 205. In the purge process (S204), a purge is performed through the exhaust pipe 262 before and after a purge is performed through the exhaust pipe 263. However, only purge the through the exhaust pipe 262 may be performed. Also, a purge through the exhaust pipe 262 and a purge through the exhaust pipe 263 can be performed at the same time.

[Second Processing Gas Supply Process (S206)]

After the purge process (S204), the valve 244d is opened to supply ammonia gas into the processing space 205 through the shower head 240.

In this case, the mass flow controller 244c is regulated such that a flow rate of ammonia gas becomes a predetermined flow rate. A flow rate of ammonia gas to be supplied may be 100 sccm and 6,000 sccm. Along with ammonia gas, N₂ gas serving as a carrier gas may also be supplied through the second inert gas supply system. In this process, the valve 245d of the third gas supply system is opened to also supply N₂ gas through the third gas supply pipe 245a.

Ammonia gas in a plasma state supplied to the chamber 202 through the first dispersion mechanism 241 is supplied onto the wafer 200. When the silicon-containing layer is modified by the ammonia gas, a layer containing a silicon element and a nitrogen element is formed on the wafer 200.

When a predetermined time elapses, the valve 244d is closed to stop the supply of the nitrogen-containing gas.

In the process (S206), similarly to the process (S202), the valve 275 is opened, and a pressure of the processing space 205 is controlled to a predetermined pressure by the APC 276. Also, the valves of the exhaust unit other than the valve 275 and the DP 278 are all closed,

[Purge Process (S208)]

Then, similarly to the process (S204), a purge process is performed. Since operations of each of the units are the same as those in the process (S204), details thereof will not be described.

[Determination (S210)]

The controller 280 determines whether a cycle including the processes is performed a predetermined number of times.

When the cycle is not performed a predetermined number of times [No in the process (S210)], the cycle including the first processing gas supply process (S202), the purge process (S204), the second processing gas supply process (S206) and the purge process (S208) is repeated. When the cycle is performed a predetermined number of times [Yes in the process (S210)], the processes illustrated in FIG. 7 end.

Referring back to FIG. 6, a substrate unloading process (S106) is then performed.

According to research results, the inventors found that, when two types of gases are alternately supplied to and exhausted from the two chambers 202a(1) and 202a(2) as in the present embodiment, as illustrated in FIG. 8, a gas A in the exhaust pipe 343 and a gas B in the exhaust pipe 343 coexist for a predetermined time. That is, the inventors found that two types of gases (the gas A and the gas B) are mixed in the exhaust pipe 343.

Such a problem is caused when a gas is quickly exchanged in order to increase a processing rate of the wafer 200. In a process of purging the gas A in order to quickly exchange a gas, the purge gas is continuously supplied for a predetermined time in order to remove the gas A in the chamber 202 (for example, the chamber 202c(1) and the chamber 202c(2)). After the predetermined time elapses, supply of the purge gas is stopped. Here, the term “predetermined time” refers to a time for which the gas A is removed from the processing space 205 of the chamber 202c(1) and the processing space 205 of the chamber 202c(2). After the predetermined time elapses, supply of the gas B immediately starts in order to increase a processing rate.

Meanwhile, during a process, a situation of the exhaust pipe 343 is as follows. Since supplying of the purge gas is stopped after the predetermined time elapses in the exhaust pipe 343, the purge gas is unable to expel a residual gas in the exhaust pipe 341 after the predetermined time elapses. This is caused by the fact that “a sum of volumes of the gas exhaust pipe 341, the gas exhaust pipe 342 and the gas exhaust pipe 343” is greater than “a sum of a volume of the processing space 205 of the chamber 202c(1) and a volume of the processing space 205 of the chamber 202c(2).” Therefore, even when supplying of the purge gas is stopped to remove the gas A from each processing space 205, a gas is remained in the gas exhaust pipe 341, the gas exhaust pipe 342 and the gas exhaust pipe 343. In particular, in the exhaust pipe 343 which is the downstream side of the gas exhaust pipe a gas significantly remains as illustrated in FIG. 8. This is similar to the gas B.

Therefore, the residual gas (for example, the gas A) and a gas (for example, the gas B) supplied thereafter are mixed in the exhaust pipe 343.

When a plurality of types of gases are mixed in this manner, by-products (for example, ammonia chloride) including salt as a main component may be generated in the exhaust pipe, and the by-products may attach to the exhaust pipe.

The attached by-products are isolated, flow back in the chamber, or decrease an inner diameter of the exhaust pipe, which negatively influence on the substrate process. Therefore, in order to prevent the by-products from being attached, it is necessary to heat the exhaust pipe to a temperature higher than a liquefaction temperature at which the by-products are liquefied under vapor pressure.

However, when cost of ownership (COO) is pursued for the cluster device as in the present embodiment, since the gas box 340 or the electronic box 350 is concentrated, heat of the heater 347 wound on the exhaust pipe 343 influences the electronic box 350 (refer to FIG. 5). Therefore, in the present embodiment, as illustrated in FIG. 3, both of the exhaust pipe 341 connected to the chamber 202c(1) and the exhaust pipe 342 connected to the chamber 202c(2) are all surrounded by one first thermal reduction structure. When both the exhaust pipe 341 and the exhaust pipe 342 are surrounded by one thermal reduction structure, it is possible to install a compact thermal reduction structure compared to when the thermal reduction structure is separately installed in each exhaust pipe below the module including a plurality of chambers as in the present embodiment. Therefore, an area in which the substrate processing apparatus 100 is installed is not increased.

Also, according to research results, the inventors found that, when two types of gases are alternately supplied to and exhausted from the two chambers 202a(1) and 202a(2) as in the present embodiment, as illustrated in FIG. 8, exhaust of the gas A in the exhaust pipe 354 and exhaust of the gas B in the exhaust pipe 354 overlap for a predetermined time. Also, the inventors found that a time for which exhaust of the gas A in the exhaust pipe 354 and exhaust of the gas B in the exhaust pipe 354 overlap is greater than a time for which the gas A in the exhaust pipe 343 and the gas B in the exhaust pipe 343 coexist.

This is caused by the fact that no pump is connected to the downstream side of the exhaust pipe 354 connected to the downstream side of the pump 344. Since no pump is connected to the downstream side of the exhaust pipe 354, it is difficult to actively discharge an atmosphere of the exhaust pipe 354. Therefore, a greater amount of gases are accumulated in the downstream side than the upstream side of the pump 344. As a result, as illustrated in FIG. 8, an area in which exhaust of the gas A in the exhaust pipe 354 and exhaust of the gas B in the exhaust pipe 354 overlap is increased.

Also, as described above, since no pump is connected, a pressure of the exhaust pipe 354 is higher than a pressure of the exhaust pipe 343. Therefore, a gas flowing from the exhaust pipe 343 to the exhaust pipe 345 through the pump 344 is changed to a liquid or a solid according to a relation of a vapor pressure curve even when the temperature is maintained.

Therefore, since a state in which the residual gas (for example, the gas A) in the exhaust pipe 354 and a gas (for example, the gas B) supplied thereafter are mixed is more significant than the exhaust pipe 343, and the pressure is high, a greater amount of by-products may be generated in the exhaust pipe 354 than the exhaust pipe 343.

Therefore, in the present embodiment, when an inner pressure of the exhaust pipe 345 is vapor pressure, the heater 358 is controlled such that a temperature of the exhaust pipe 345 is maintained at a temperature at which the source gas is vaporized. When the heater 358 is controlled in this manner, it is possible to suppress by-products from being generated in the exhaust pipe 345.

Also, by setting a temperature at which the exhaust pipe 345 is heated to be higher than a temperature at which the exhaust pipe 343 is heated, a gas can be exhausted without being accumulated before and after the pump. Also, as illustrated in FIG. 9, the third thermal reduction structure 356 is installed at an outer circumference of the exhaust pipe 345. In this manner, when at least two or more exhaust pipes 354a to 354d are completely insulated with the one third thermal reduction structure, it is possible to provide the compact substrate processing apparatus 100.

[Substrate Unloading Process (S106)]

In the substrate unloading process (S106), by lowering the substrate placing table 212, the wafer 200 is supported on the lift pins 207 protruding from a surface of the substrate placing table 212. Therefore, the wafer 200 is moved from the processing position to the transfer position. During this time, the arm 180 is cooled. Next, the gate valve 149 is opened, and the arm 180 is used to unload the wafer 200 from the chamber 202. In this case, when the valve 245d is closed, supply of the inert gas into the chamber 202 through the third gas supply system is stopped.

Then, when the wafer 200 is moved to the transfer position, the valve 275 is closed to block between the processing space 205 and the exhaust pipe 264. On the other hand, when the valve 266 and the valve 267 are opened and an atmosphere of the transfer space 303 is exhausted by the TMP 265 (and the DP 278), the chamber 202 is maintained in a high vacuum (ultra-high vacuum) state (for example, 10⁻⁵ Pa or lower) and a pressure difference with a transfer chamber in which a high vacuum (ultra-high vacuum) state (for example, 10⁻⁶ Pa or lower) is maintained is reduced.

[Processing Unprocessed Wafer]

The steps S102, S104 and S106 may be performed to an unprocessed wafer.

While the film-forming technique has been described above as various typical embodiments of the present invention, the present invention is not limited to such embodiments. For example, the present invention can be applied to a process in which a thin film other than the above-exemplified thin film is formed or when other substrate processes such as diffusion treatment, oxidation treatment, nitridation treatment and lithographic treatment are performed. Also, the present invention can be applied to an annealing processing device and other substrate processing apparatuses such as a thin film-forming device, an etching device, an oxidation treatment device, a nitridation treatment device, a coating device, and a heating device. Also, some configurations of an embodiment may be replaced with configurations of another embodiment, and a configuration of another embodiment may be added to a configuration of an embodiment. Also, other configurations can be added to, deleted from, or substituted with, some configurations of each embodiment.

Also, in the above embodiments, while DCS is exemplified as the first element-containing gas and silicon is exemplified as the first element, the present invention is not limited thereto. For example, the first element may be an element such as Ti, Zr or Hf. Also, while NH₃ is exemplified as the second element-containing gas and nitrogen is exemplified as the second element, the present invention is not limited thereto. The second element may be, for example, oxygen.

According to the present invention, there is provided a technique through which it is possible to perform a high-temperature process in a device including a plurality of chambers.

1. A substrate processing apparatus comprising:
a plurality of process modules, each of the plurality of process modules comprising a plurality of chambers where substrates are processed, wherein the plurality of chambers are disposed adjacent to one another;
a gas supply unit configured to alternately supply a first gas and a second gas to each of the plurality of chambers;
a first exhaust pipe configured to exhaust the first gas and the second gas;
a first heater installed at the first exhaust pipe and configured to heat the first exhaust pipe to a temperature higher than a temperature whereat a source of the first gas is vaporized under vapor pressure;
a plurality of gas boxes, each of the plurality of gas boxes disposed below each of the plurality of process modules and accommodating a portion of the first exhaust pipe;
a plurality of electronic boxes, each of the plurality of electronic boxes installed at each of the plurality of chambers and disposed below each of the plurality of process modules to be adjacent to each of the plurality of gas boxes;
a first thermal reduction structure surrounding the first exhaust pipe and configured to reduce a heat from the first heater being conducted to the plurality of electronic boxes;
a vacuum transfer chamber having the plurality of process modules disposed therearound;
a vacuum transfer robot disposed in the vacuum transfer chamber at a center thereof;
a shaft of the vacuum transfer robot installed at a bottom portion of the vacuum transfer chamber; and
a second thermal reduction structure disposed below the vacuum transfer chamber between the shaft and the plurality of gas boxes to surround an outer circumference of the shaft of the vacuum transfer robot.

2. The substrate processing apparatus of claim 1, further comprising:
a pump installed at the first exhaust pipe;
a second exhaust pipe connected between a downstream side of the pump and a harm removing device; and
a second heater installed at the second exhaust pipe and configured to heat the second exhaust pipe to a temperature higher than a temperature of the first exhaust pipe.

3. The substrate processing apparatus of claim 2, wherein the first exhaust pipe comprises an elbow-shaped portion, and the first thermal reduction structure surrounds at least the elbow-shaped portion.

4. The substrate processing apparatus of claim 1, wherein the plurality of process modules are disposed radially about the vacuum transfer chamber.

5. (canceled)

6. The substrate processing apparatus of claim 1, wherein the second thermal reduction structure is cylindrical.

7. The substrate processing apparatus of claim 3, further comprising: an atmosphere controller configured to control an inner atmosphere of the first thermal reduction structure, wherein the first thermal reduction structure comprises a room serving as a vacuum space and the atmosphere controller is disposed in the room.

8. The substrate processing apparatus of claim 7, further comprising:
a third exhaust pipe installed at the atmosphere controller, and
the pump is connected between the first exhaust pipe and a downstream side of the third exhaust pipe.

9.-15. (canceled)

16. The substrate processing apparatus of claim 1, wherein the first gas comprises a source gas containing a halide, and the second gas comprises a gas reactive with the source gas.

17. The substrate processing apparatus of claim 1, further comprising: an exhaust controller connected to one end of the first exhaust pipe, wherein other end of the first exhaust pipe is connected to the plurality of chambers, and a main part of the first exhaust pipe between the one end and the other end is disposed below the plurality of chambers.
